(19) United States
(12) Patent Application Publication
(10) Pub. No.: US 2017/0339355 A1
(43) Pub. Date: Nov. 23, 2017

(54) IMAGING SYSTEMS WITH GLOBAL SHUTTER PHASE DETECTION PIXELS

(71) Applicant: SEMICONDUCTOR COMPONENTS INDUSTRIES, LLC, Phoenix, AZ (US)

(72) Inventors: Victor LENCHENKOV, Sunnyvale, CA (US); Ulrich BOETTIGER, Garden City, ID (US)

(73) Assignee: SEMICONDUCTOR COMPONENTS INDUSTRIES, LLC, Phoenix, AZ (US)

(21) Appl. No.: 15/159,500

(22) Filed: May 19, 2016

(51) Int. Cl. H04N 5/369; H01L 27/146

(52) U.S. Cl. CPC H04N 5/3696; H01L 27/1463; H01L 27/1462; H01L 27/14623; H01L 27/14627

(57) ABSTRACT

An image sensor may include a pixel array with global shutter phase detection pixels. The global shutter phase detection pixels may include global shutter charge storage regions. To prevent the global shutter charge storage regions from being exposed to incident light, a shielding layer may be provided. The shielding layer may also cover portions of underlying photodiodes to produce an asymmetric response to incident light in the underlying photodiodes. The shielding layer may be formed as backside trench isolation with an absorptive metal. The absorptive metal may absorb incident light, reducing the likelihood of the incident light reaching the charge storage regions. An additional absorptive layer may also be provided on or in the shielding layer.

### BACKGROUND

This relates generally to imaging systems and, more particularly, to imaging systems with phase detection capabilities.

Modern electronic devices such as cellular telephones, cameras, and computers often use digital image sensors. Imager sensors (sometimes referred to as imagers) may be formed from a two-dimensional array of image sensing pixels. Each pixel receives incident photons (light) and converts the photons into electrical signals. Image sensors are sometimes designed to provide images to electronic devices using a Joint Photographic Experts Group (JPEG) format.

Some applications such as automatic focusing and three-dimensional (3D) imaging may require electronic devices to provide stereo and/or depth sensing capabilities. For example, to bring an object of interest into focus for an image capture, an electronic device may need to identify the distances between the electronic device and object of interest. To identify distances, conventional electronic devices use complex arrangements. Some arrangements require the use of multiple image sensors and camera lenses that capture images from various viewpoints. Other arrangements require the addition of lenticular arrays that focus incident light on sub-regions of a two-dimensional pixel array. Due to the addition of components such as additional image sensors or complex lens arrays, these arrangements lead to reduced spatial resolution, increased cost, and increased complexity.

It would therefore be desirable to be able to provide improved imaging systems with depth sensing capabilities.

### BRIEF DESCRIPTION OF THE DRAWINGS

FIG. 1 is a schematic diagram of an illustrative electronic device with an image sensor that may include phase detection pixels in accordance with an embodiment of the present invention.

FIG. 2A is a cross-sectional side view of illustrative phase detection pixels having photosensitive regions with different and asymmetric angular responses in accordance with an embodiment of the present invention.

FIGS. 2B and 2C are cross-sectional views of the phase detection pixels of FIG. 2A in accordance with an embodiment of the present invention.

FIG. 3 is a diagram of illustrative signal outputs of photosensitive regions of depth sensing pixels for incident light striking the depth sensing pixels at varying angles of incidence in accordance with an embodiment of the present invention.

FIG. 4 is a cross-sectional side view of an illustrative image sensor with a shielding layer for a global shutter storage region in accordance with an embodiment of the present invention.

FIG. 5 is a cross-sectional side view of an illustrative image sensor with a backside trench isolation shielding layer for a global shutter storage region in accordance with an embodiment of the present invention.

FIG. 6 is a cross-sectional side view of an illustrative image sensor with a shielding layer that has an absorptive coating in accordance with an embodiment of the present invention.

FIG. 7 is a cross-sectional side view of an illustrative image sensor with a shielding layer and an absorptive layer embedded in the shielding layer in accordance with an embodiment of the present invention.

FIG. 8 is a top view of an illustrative image sensor with a shielding layer and a charge storage region in accordance with an embodiment of the present invention.

FIG. 9 is a top view of an illustrative image sensor with a shielding layer and charge storage regions in accordance with an embodiment of the present invention.

FIG. 10 is a top view of an illustrative image sensor that has 2×2 grids of pixels covered by a single microlens as well as shielding layers and charge storage regions in accordance with an embodiment of the present invention.

FIG. 11 is a top view of an illustrative image sensor that has elliptical microlenses as well as shielding layers and charge storage regions in accordance with an embodiment of the present invention.

### DETAILED DESCRIPTION

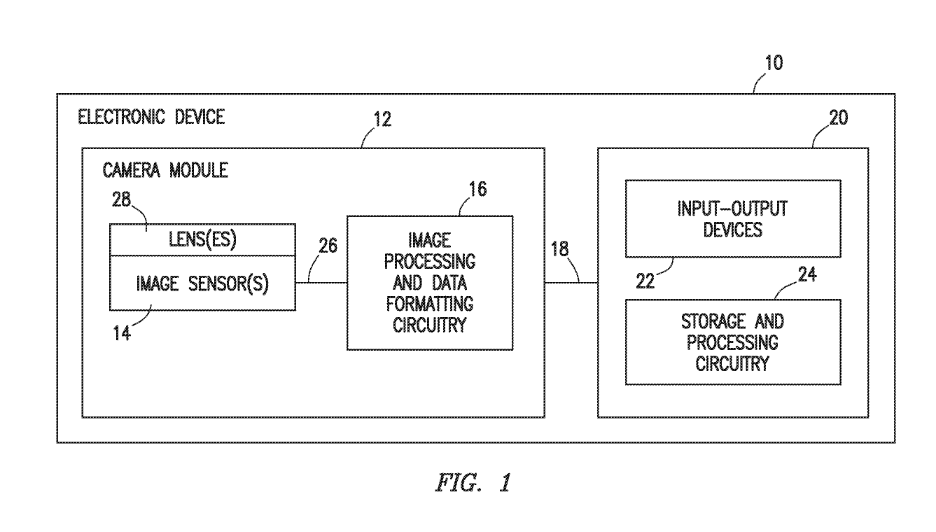

Embodiments of the present invention relate to image sensors with depth sensing capabilities. An electronic device with a digital camera module is shown in FIG. 1. Electronic device 10 may be a digital camera, a computer, a cellular telephone, a medical device, or other electronic device. Camera module 12 (sometimes referred to as an imaging device) may include image sensor 14 and one or more lenses 28. During operation, lenses 28 (sometimes referred to as optics 28) focus light onto image sensor 14. Image sensor 14 includes photosensitive elements (e.g., pixels) that convert the light into digital data. Image sensors may have any number of pixels (e.g., hundreds, thousands, millions, or more). A typical image sensor may, for example, have millions of pixels (e.g., megapixels). As examples, image sensor 14 may include bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc.

Still and video image data from image sensor 14 may be provided to image processing and data formatting circuitry 16 via path 26. Image processing and data formatting circuitry 16 may be used to perform image processing functions such as automatic focusing functions, depth sensing, data formatting, adjusting white balance and exposure, implementing video image stabilization, face detection, etc. For example, during automatic focusing operations, image processing and data formatting circuitry 16 may process data gathered by phase detection pixels in image sensor 14 to determine the magnitude and direction of lens movement (e.g., movement of lens 28) needed to bring an object of interest into focus.

Image processing and data formatting circuitry 16 may also be used to compress raw camera image files if desired (e.g., to Joint Photographic Experts Group or JPEG format). In a typical arrangement, which is sometimes referred to as a system on chip (SOC) arrangement, camera sensor 14 and image processing and data formatting circuitry 16 are implemented on a common integrated circuit. The use of a single integrated circuit to implement camera sensor 14 and image processing and data formatting circuitry 16 can help to reduce costs. This is, however, merely illustrative. If desired, camera sensor 14 and image processing and data formatting circuitry 16 may be implemented using separate integrated circuits. If desired, camera sensor 14 and image processing circuitry 16 may be formed on separate semiconductor substrates. For example, camera sensor 14 and image processing circuitry 16 may be formed on separate substrates that have been stacked.

Camera module 12 may convey acquired image data to host subsystems 20 over path 18 (e.g., image processing and data formatting circuitry 16 may convey image data to subsystems 20). Electronic device 10 typically provides a user with numerous high-level functions. In a computer or advanced cellular telephone, for example, a user may be provided with the ability to run user applications. To implement these functions, host subsystem 20 of electronic device 10 may include storage and processing circuitry 24 and input-output devices 22 such as keypads, input-output ports, joysticks, and displays. Storage and processing circuitry 24 may include volatile and nonvolatile memory (e.g., random-access memory, flash memory, hard drives, solid state drives, etc.). Storage and processing circuitry 24 may also include microprocessors, microcontrollers, digital signal processors, application specific integrated circuits, or other processing circuits.

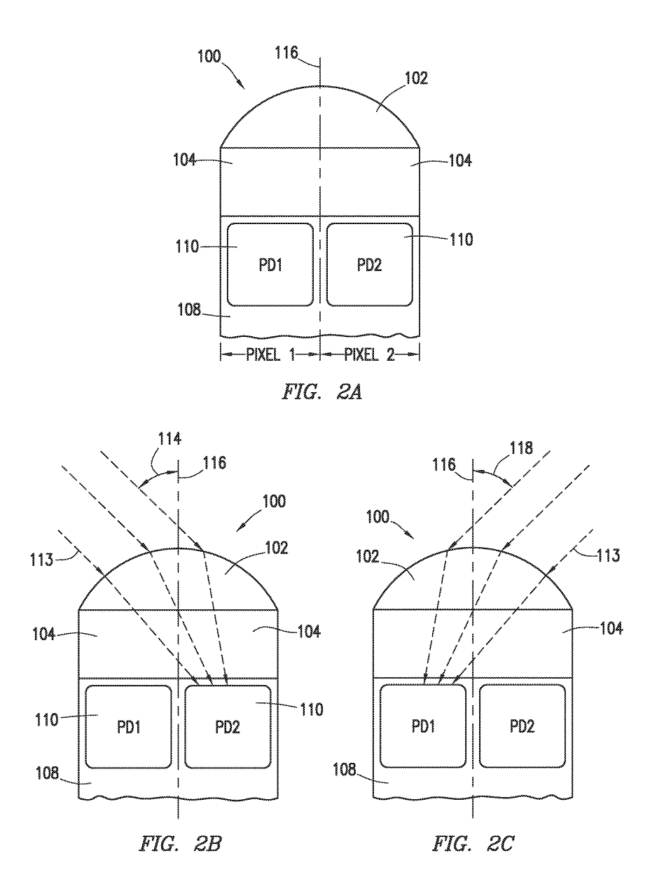

It may be desirable to provide image sensors with depth sensing capabilities (e.g., to use in automatic focusing applications, 3D imaging applications such as machine vision applications, etc.). To provide depth sensing capabilities, image sensor 14 may include phase detection pixel groups such as phase detection pixel group 100 shown in FIG. 2A.

FIG. 2A is an illustrative cross-sectional view of pixel group 100. In FIG. 2A, phase detection pixel group 100 is a pixel pair. Pixel pair 100 may include first and second pixels such Pixel 1 and Pixel 2. Pixel 1 and Pixel 2 may include photosensitive regions such as photosensitive regions 110 formed in a substrate such as silicon substrate 108. For example, Pixel 1 may include an associated photosensitive region such as photodiode PD1, and Pixel 2 may include an associated photosensitive region such as photodiode PD2. A microlens may be formed over photodiodes PD1 and PD2 and may be used to direct incident light towards photodiodes PD1 and PD2. The arrangement of FIG. 2A in which microlens 102 covers two pixel regions may sometimes be referred to as a 2×1 or 1×2 arrangement because there are two phase detection pixels arranged consecutively in a line. In an alternate embodiment, three phase detection pixels may be arranged consecutively in a line in what may sometimes be referred to as a 1×3 or 3×1 arrangement.

Color filters such as color filter elements 104 may be interposed between microlens 102 and substrate 108. Color filter elements 104 may filter incident light by only allowing predetermined wavelengths to pass through color filter elements 104 (e.g., color filter 104 may only be transparent to the wavelengths corresponding to a green color, a red color, a blue color, a yellow color, a cyan color, a magenta color, visible light, infrared light, etc.). Color filter 104 may be a broadband color filter. Examples of broadband color filters include yellow color filters (e.g., yellow color filter material that passes red and green light) and clear color filters (e.g., transparent material that passes red, blue, and green light). In general, broadband filter elements may pass two or more colors of light. Photodiodes PD1 and PD2 may serve to absorb incident light focused by microlens 102 and produce pixel signals that correspond to the amount of incident light absorbed.

Photodiodes PD1 and PD2 may each cover approximately half of the substrate area under microlens 102 (as an example). By only covering half of the substrate area, each photosensitive region may be provided with an asymmetric angular response (e.g., photodiode PD1 may produce different image signals based on the angle at which incident light reaches pixel pair 100). The angle at which incident light reaches pixel pair 100 relative to a normal axis 116 (i.e., the angle at which incident light strikes microlens 102 relative to the optical axis 116 of lens 102) may be herein referred to as the incident angle or angle of incidence.

An image sensor can be formed using front side illumination imager arrangements (e.g., when circuitry such as metal interconnect circuitry is interposed between the microlens and photosensitive regions) or back side illumination imager arrangements (e.g., when photosensitive regions are interposed between the microlens and the metal interconnect circuitry). The example of FIGS. 2A, 2B, and 2C in which pixels 1 and 2 are backside illuminated image sensor pixels is merely illustrative. If desired, pixels 1 and 2 may be front side illuminated image sensor pixels. Arrangements in which pixels are backside illuminated image sensor pixels are sometimes described herein as an example.

In the example of FIG. 2B, incident light 113 may originate from the left of normal axis 116 and may reach pixel pair 100 with an angle 114 relative to normal axis 116. Angle 114 may be a negative angle of incident light. Incident light 113 that reaches microlens 102 at a negative angle such as angle 114 may be focused towards photodiode PD2. In this scenario, photodiode PD2 may produce relatively high image signals, whereas photodiode PD1 may produce relatively low image signals (e.g., because incident light 113 is not focused towards photodiode PD1).

In the example of FIG. 2C, incident light 113 may originate from the right of normal axis 116 and reach pixel pair 100 with an angle 118 relative to normal axis 116. Angle 118 may be a positive angle of incident light. Incident light that reaches microlens 102 at a positive angle such as angle 118 may be focused towards photodiode PD1 (e.g., the light is not focused towards photodiode PD2). In this scenario, photodiode PD2 may produce an image signal output that is relatively low, whereas photodiode PD1 may produce an image signal output that is relatively high.

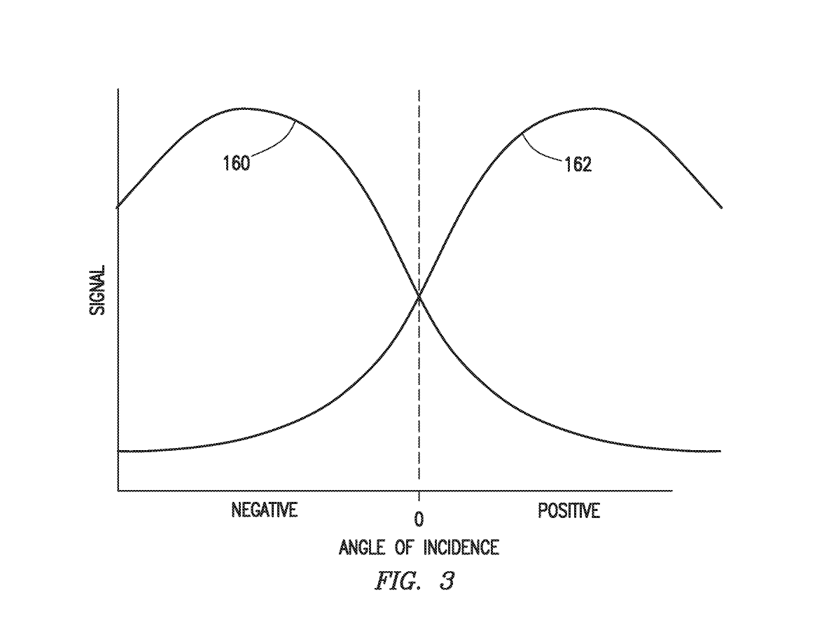

The positions of photodiodes PD1 and PD2 may sometimes be referred to as asymmetric positions because the center of each photosensitive area 110 is offset from (i.e., not aligned with) optical axis 116 of microlens 102. Due to the asymmetric formation of individual photodiodes PD1 and PD2 in substrate 108, each photosensitive area 110 may have an asymmetric angular response (e.g., the signal output produced by each photodiode 110 in response to incident light with a given intensity may vary based on an angle of incidence). In the diagram of FIG. 3, an example of the image signal outputs of photodiodes PD1 and PD2 of pixel pair 100 in response to varying angles of incident light is shown.

Line 160 may represent the output image signal for photodiode PD2 whereas line 162 may represent the output image signal for photodiode PD1. For negative angles of incidence, the output image signal for photodiode PD2 may increase (e.g., because incident light is focused onto photodiode PD2) and the output image signal for photodiode PD1 may decrease (e.g., because incident light is focused away from photodiode PD1). For positive angles of incidence, the output image signal for photodiode PD2 may be relatively small and the output image signal for photodiode PD1 may be relatively large.

The size and location of photodiodes PD1 and PD2 of pixel pair 100 of FIGS. 2A, 2B, and 2C are merely illustrative. If desired, the edges of photodiodes PD1 and PD2 may be located at the center of pixel pair 100 or may be shifted slightly away from the center of pixel pair 100 in any direction. If desired, photodiodes 110 may be decreased in size to cover less than half of the pixel area.

Output signals from pixel pairs such as pixel pair 100 may be used to adjust the optics (e.g., one or more lenses such as lenses 28 of FIG. 1) in image sensor 14 during automatic focusing operations. The direction and magnitude of lens movement needed to bring an object of interest into focus may be determined based on the output signals from pixel pairs 100.

For example, by creating pairs of pixels that are sensitive to light from one side of the lens or the other, a phase difference can be determined. This phase difference may be used to determine both how far and in which direction the image sensor optics should be adjusted to bring the object of interest into focus.

When an object is in focus, light from both sides of the image sensor optics converges to create a focused image. When an object is out of focus, the images projected by two sides of the optics do not overlap because they are out of phase with one another. By creating pairs of pixels where each pixel is sensitive to light from one side of the lens or the other, a phase difference can be determined. This phase difference can be used to determine the direction and magnitude of optics movement needed to bring the images into phase and thereby focus the object of interest. Pixel groups that are used to determine phase difference information such as pixel pair 100 are sometimes referred to herein as phase detection pixels or depth-sensing pixels.

A phase difference signal may be calculated by comparing the output pixel signal of PD1 with that of PD2. For example, a phase difference signal for pixel pair 100 may be determined by subtracting the pixel signal output of PD1 from the pixel signal output of PD2 (e.g., by subtracting line 162 from line 160). For an object at a distance that is less than the focused object distance, the phase difference signal may be negative. For an object at a distance that is greater than the focused object distance, the phase difference signal may be positive. This information may be used to automatically adjust the image sensor optics to bring the object of interest into focus (e.g., by bringing the pixel signals into phase with one another).

As previously mentioned, the example in FIGS. 2A-2C where phase detection pixel group 100 includes two adjacent pixels is merely illustrative. Phase detection pixel group 100 may include three adjacent pixels, a 2×2 group of pixels, a 2×4 group of pixels, a 4×4 group of pixels, or a group of pixels of any other desired size.

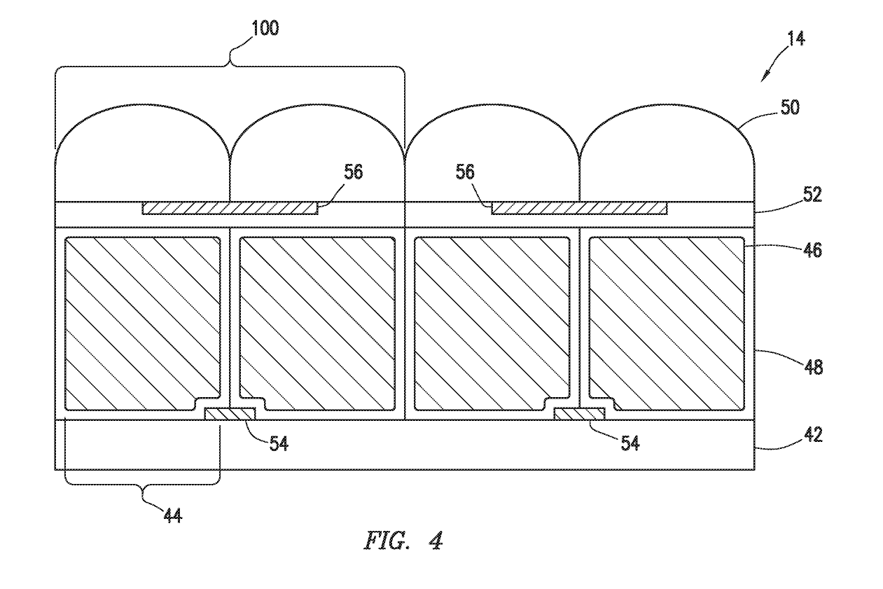

Image sensors can operate using a global shutter or a rolling shutter scheme. In a global shutter, every pixel in the image sensor may simultaneously capture an image, whereas in a rolling shutter each row of pixels may sequentially capture an image. In order to implement global shutter, a pixel may include a storage node for storing charge from the photodiode. FIGS. 4-11 show illustrative pixels with storage nodes.

FIG. 4 is a cross-sectional side view of illustrative phase detection pixels with a storage node covered by a shielding layer. As shown in FIG. 4, the pixels may be formed on substrate 42. Substrate 42 may be formed from any desired material (e.g., boron phosphorous silicon glass). On substrate 42, photodiodes 46 for each pixel 44 may be formed in substrate 48. Substrate 48 may be a silicon substrate, and photodiodes 46 may be a doped portion of the silicon substrate. As shown in FIG. 4, each pixel may include a microlens 50. A color filter layer 52 may be positioned between the pixels and the microlenses. In FIG. 4, microlenses 50 are shown as being formed on the back side of silicon substrate 48, and the pixels may therefore be referred to as backside illuminated pixels. However, this example is merely illustrative and the pixels may be front side illuminated pixels if desired.

A storage region 54 may also be provided for one or more of pixels 44. Storage region 54 may be a doped-semiconductor region. For example, storage region 54 may be a doped-silicon region. Each storage region 54 may be capable of storing charge from one or more photodiode. However, the storage region (sometimes referred to as a storage node) may also collect charge that was not generated in a photodiode. This is generally not desirable as the charge from the photodiode stored in the storage node will be affected by noise if the storage node collects additional charge. To reduce noise, it is preferable to limit the exposure of each storage region 54 to incident light. In order to reduce how much incident light reaches storage node 54, a shielding layer 56 may be provided above the storage node. Shielding layer 56 may be formed from a material that is opaque to visible light (e.g., tungsten, metal oxide, a composite material, etc.). It may also be desirable for shielding layer 56 to be an absorptive material that absorbs incident light as opposed to reflecting it. If shielding layer 56 is reflective, incident light may reflect off of the sidewalls of the shielding layer and end up reaching storage node 54. By absorbing any incident light, shielding layer 56 better reduces noise in the image sensor.

Shielding layer 56 may also ensure that the underlying photodiodes have an asymmetric response to incident light. In other words, shielding layer 56 may cover approximately half of two neighboring photodiodes to make a phase detection pixel pair 100. Shielding layer 56 does not have to cover half of the underlying photodiodes, and can cover any portion of the underlying photodiodes (e.g., 0.3×, 0.4×, 0.6×, between 0.3× and 0.6×, less than 0.3×, more than 0.3×, etc.). Storage node 54 may be used to store charge for any desired photodiodes. In an illustrative embodiment, each storage region 54 shown in FIG. 4 may actually represent two separately formed storage regions, with charge from each photodiode being stored in a respective storage region.

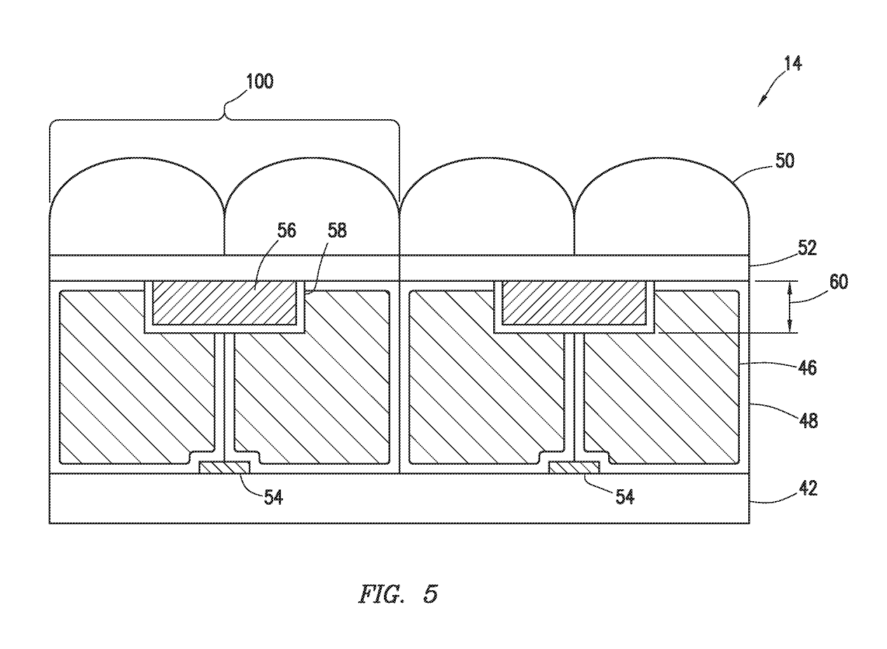

In FIG. 4, shielding layer 56 is shown as being embedded in color filter layer 52. This example is merely illustrative. As shown in FIG. 5, shielding layer 56 may be formed as backside trench isolation. Shielding layer 56 may be formed in a trench that extends into semiconductor substrate 48. As previously discussed in connection with FIG. 4, shielding layer 56 may be formed from an absorptive material that is opaque to visible light. An anti-reflective coating or liner 58 may also be included in the trench around shielding layer 56.

Forming shielding layer 56 as backside trench isolation may allow for better protection of storage region 54 from noise. The backside trench isolation has a depth 60. In other words, the trench for the backside trench isolation extends from a back surface of substrate 48 towards a front surface of substrate 48 some distance 60. This enhanced depth provides greater shielding of storage region 54, and also may improve the asymmetric response to incident light of the pixels in phase detection pixel group 100. The depth, width, and height of shielding layer 56 may be chosen to optimize the amount of noise exposed to charge storage region 54 and phase detection performance of the phase detection pixels.

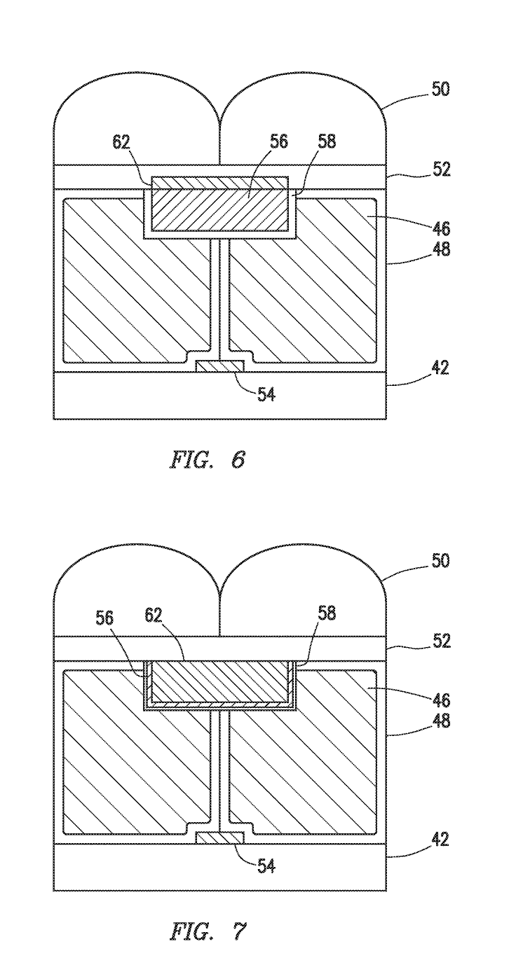

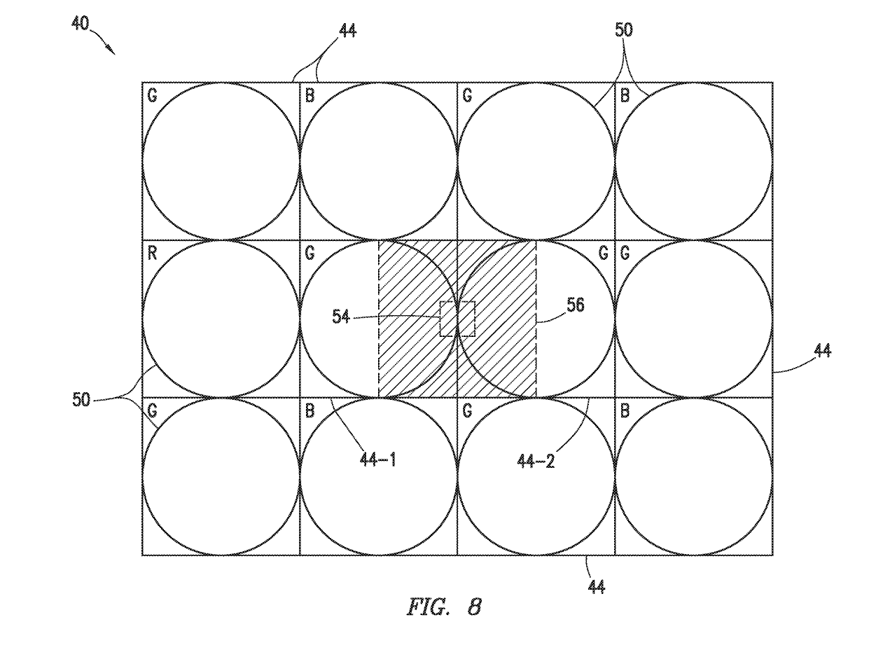

If desired, an additional absorptive layer 62 may be provided in addition to shielding layer 56, as shown in FIG. 6. Absorptive layer 62 may be formed from any desired material. Exemplary materials for absorptive layer 62 may include a polymeric pigment loaded material, a carbon black material, a black color filter, or a material with carbon nanoparticles. As shown in FIG. 6, absorptive layer 62 may be formed as a coating on the top of shielding layer 56. However, this example is merely illustrative. As shown in FIG. 7, absorptive layer 62 may instead be embedded within the trench for the backside trench isolation. The aforementioned examples of possible positions for an absorptive layer are merely illustrative. If desired the top and side surfaces of shielding layer 56 may be coated with absorptive layer 62. In general, absorptive layer 62 may be formed on or in any desired portion of shielding layer 56.

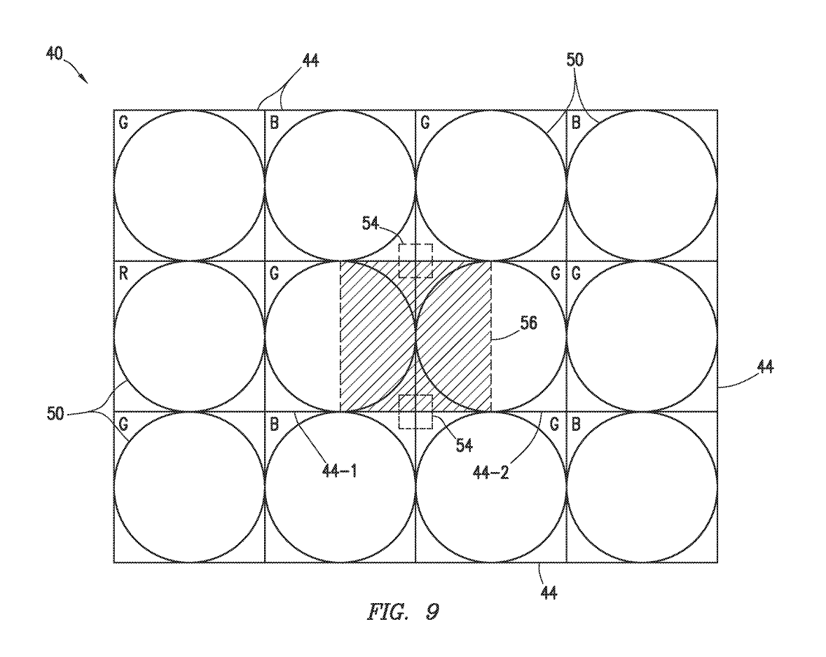

FIG. 8 shows an illustrative pixel array 40. Pixel array 40 includes a color filter array. Pixels marked with an R include a red color filter, pixels marked with a G include a green color filter, and pixels marked with a B include a blue color filter. The pattern of color filters in pixel array 100 is a Bayer mosaic pattern which includes a repeating unit cell of two-by-two image pixels 44 having two green image pixels arranged on one diagonal and one red and one blue image pixel arranged on the other diagonal. This example is merely illustrative, and other color filter patterns may be used if desired. For example, a broadband color filter (e.g., a yellow or clear color filter) may be used instead of a green color filter in the color filter array.

In FIG. 8, pixels 44-1 and 44-2 may form a phase detection pixel pair 100. FIG. 8 may show a top view of a phase detection pixel pair of the type previously shown in FIGS. 4-7. As shown, shielding layer 56 is formed over a portion of each of pixels 44-1 and 44-2. This creates an asymmetric angular response in the photodiodes of pixels 44-1 and 44-2 for phase detection. Additionally, shielding layer 56 may shield underlying storage node 54 from incident light. As shown in FIG. 8, storage node 54 may be formed in between pixels 44-1 and 44-2. Storage node 54 may be configured to store charge from either pixel 44-1 or pixel 44-2. Alternatively, storage region 54 may include two separate storage nodes, one of which stores charge from pixel 44-1 and another that stores charge from pixel 44-2. The example of FIG. 8 is merely illustrative, and storage region 54 may be formed at any desired location in the pixel array.

FIG. 9 shows another illustrative embodiment for a shielding layer that shields storage nodes from incident light. Shielding layer 56 in FIG. 9 provides an asymmetric response in pixels 44-1 and 44-2, similar to the shielding layer in FIG. 8. However, in FIG. 9 there are two storage regions 54 formed under shielding layer 56. Each storage region may be formed at a corner of four pixels. The shielding layer may help shield at least some of the storage region. Additional shielding structures may be formed in the adjacent pixels to shield additional portions of the storage regions.

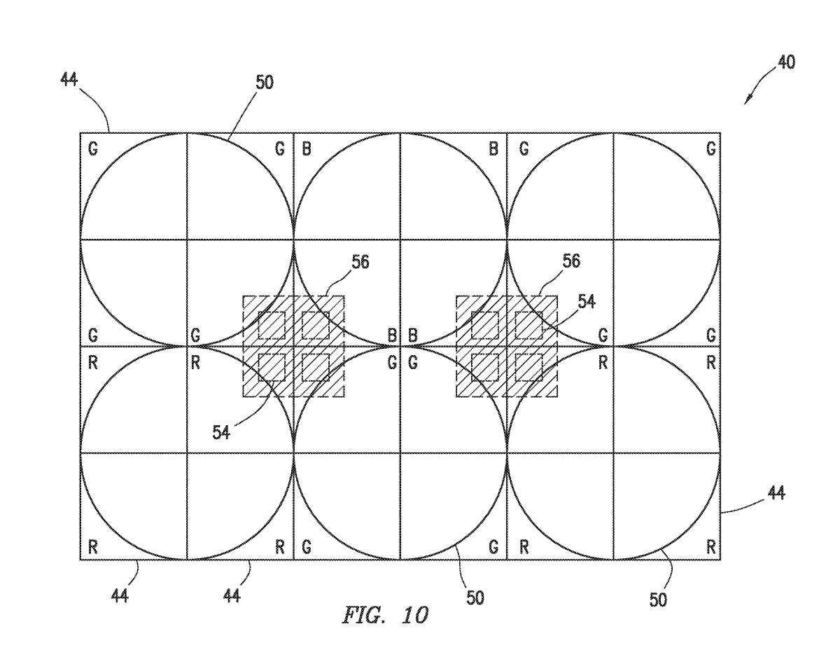

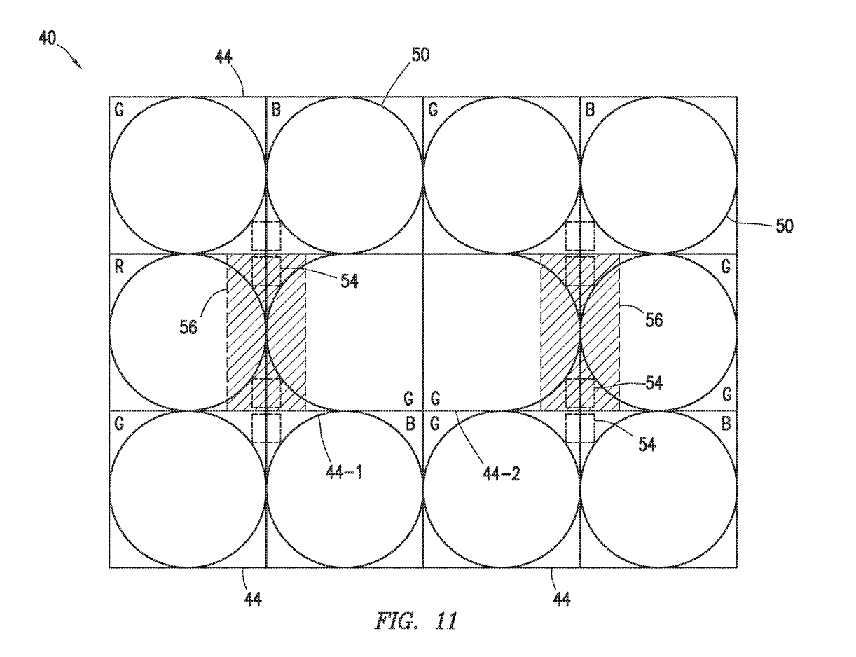

Shielding layer 56 does not have to be the only component that contributes to the asymmetric response of the pixels in each phase detection pixel group 100. As shown in FIG. 10, phase detection pixel groups 100 may include four pixels in a 2×2 grid that are covered by a single microlens 50. The pixels in each phase detection pixel group may have a single color. However, this example is merely illustrative and any desired color filter elements may be used for each pixel. As shown in FIG. 10, shielding layer 56 may be formed at a corner between four pixels in different phase detection pixel groups. The shielding layer may cover four different storage regions, each of which is associated with a respective pixel in a respective phase detection pixel group. In the example of FIG. 10, the asymmetric response of each pixel may be caused primarily due to the arrangement of the photodiode with respect to the larger microlens. However, shielding structure 56 may still ensure that storage regions 54 are shielded from incident light.

FIG. 11 is a top view of an illustrative pixel array with phase detection pixel group covered by an elliptical microlens. Similar to FIG. 10, the asymmetric response of pixels 44-1 and 44-2 in FIG. 11 may be caused primarily due to the arrangement of the photodiodes with respect to the elliptical microlens. However, shielding layer 56 may provide shielding for various storage nodes 54. Shielding layer 56 may shield storage nodes that are associated with phase detection pixels 44-1 and 44-2 and storage nodes that are not associated with phase detection pixels 44-1 and 44-2. Storage nodes may also be provided in the array that are not shielded by shielding layer 56. These storage nodes may be shielded by other shielding structures if desired.

Storage regions 54 as described in connection with FIGS. 4-11 may be used as storage regions to implement a global shutter mode in image sensor 14. However, this example is merely illustrative, and the storage regions may be used for any desired purpose (e.g., storing image data for high dynamic range applications, storing image data for flicker mitigation techniques, etc.).

In various embodiments of the invention, an image sensor may include a pixel array. The pixel array may include a first global shutter phase detection pixel with a first photodiode that is covered by a first microlens, a second global shutter phase detection pixel with a second photodiode that is covered by a second microlens, an shielding layer that covers at least a portion of the first photodiode and at least a portion of the second photodiode, and a charge storage region formed underneath the shielding layer. The shielding layer may shield the charge storage region from incident light.

The shielding layer may be opaque to visible light. The shielding layer may be formed from an absorptive material. The shielding layer may include tungsten. The shielding layer may include backside trench isolation. The shielding layer may be coated with an anti-reflective coating. The shielding layer may be coated with an absorptive coating. The shielding layer may cover approximately half of the first photodiode and approximately half of the second photodiode.

In various embodiments, an image sensor may include a silicon substrate with first and second opposing sides, a first photodiode for a first phase detection pixel formed in the silicon substrate, a second photodiode for a second phase detection pixel formed in the silicon substrate, a trench formed in the silicon substrate that extends from the first side of the silicon substrate towards the second side of the silicon substrate, a shielding layer formed in the trench, and a global shutter storage region formed in the silicon substrate. The shielding layer may overlap the global shutter storage region.

The shielding layer may cover at least a portion of the first photodiode and at least a portion of the second photodiode. The shielding layer may cover approximately half of the first photodiode and approximately half of the second photodiode. The shielding layer may be formed from an absorptive material that absorbs incident light. The image sensor may also include an anti-reflective coating on the shielding layer and an absorptive coating on the shielding layer. The image sensor may also include a first microlens formed over the first photodiode and a second microlens formed over the second photodiode. The first and second microlenses may be formed on the first side of the silicon substrate. The global shutter storage region may be formed in the second side of the silicon substrate.

In various embodiments, an image sensor may include a substrate with a front side and an opposing back side, a first photodiode for a first phase detection pixel formed in the substrate, a second photodiode for a second phase detection pixel formed in the substrate, a first microlens on the back side of the substrate that covers the first photodiode, a second microlens on the back side of the substrate that covers the second photodiode, back side trench isolation formed in the substrate that extends from the back side of the substrate towards the front side of the substrate, and a storage region formed in the substrate. The back side trench isolation may overlap the first and second photodiodes, and the back side trench isolation may shield the storage region from incident light. The back side trench isolation may overlap approximately half of the first photodiode and approximately half of the second photodiode. The back side trench isolation may include tungsten and an anti-reflective coating. The first and second phase detection pixels may be configured to operate in a global shutter mode, and the storage region may be a global shutter storage region.

The foregoing is merely illustrative of the principles of this invention and various modifications can be made by those skilled in the art without departing from the scope and spirit of the invention.

What is claimed is:

1. An image sensor having a pixel array, wherein the pixel array comprises:
a first global shutter phase detection pixel with a first photodiode that is covered by a first microlens;
a second global shutter phase detection pixel with a second photodiode that is covered by a second microlens;
an shielding layer that covers at least a portion of the first photodiode and at least a portion of the second photodiode; and
a charge storage region formed underneath the shielding layer, wherein the shielding layer shields the charge storage region from incident light.

2. The image sensor defined in claim 1, wherein the shielding layer is opaque to visible light.

3. The image sensor defined in claim 2, wherein the shielding layer is formed from an absorptive material.

4. The image sensor defined in claim 3, wherein the shielding layer comprises tungsten.

5. The image sensor defined in claim 1, wherein the shielding layer comprises backside trench isolation.

6. The image sensor defined in claim 5, wherein the shielding layer is coated with an anti-reflective coating.

7. The image sensor defined in claim 6, wherein the shielding layer is coated with an absorptive coating.

8. The image sensor defined in claim 1, wherein the shielding layer covers approximately half of the first photodiode and approximately half of the second photodiode.

9. An image sensor comprising:
a silicon substrate with first and second opposing sides;
a first photodiode for a first phase detection pixel formed in the silicon substrate;
a second photodiode for a second phase detection pixel formed in the silicon substrate;
a trench formed in the silicon substrate that extends from the first side of the silicon substrate towards the second side of the silicon substrate;
a shielding layer formed in the trench; and
a global shutter storage region formed in the silicon substrate, wherein the shielding layer overlaps the global shutter storage region.

10. The image sensor defined in claim 9, wherein the shielding layer covers at least a portion of the first photodiode and at least a portion of the second photodiode.

11. The image sensor defined in claim 10, wherein the shielding layer covers approximately half of the first photodiode and approximately half of the second photodiode.

12. The image sensor defined in claim 11, wherein the shielding layer is formed from an absorptive material that absorbs incident light.

13. The image sensor defined in claim 12, further comprising:
an anti-reflective coating on the shielding layer.

14. The image sensor defined in claim 13, further comprising:
an absorptive coating on the shielding layer.

15. The image sensor defined in claim 9, further comprising:
a first microlens formed over the first photodiode; and
a second microlens formed over the second photodiode, wherein the first and second microlenses are formed on the first side of the silicon substrate.

16. The image sensor defined in claim 15, wherein the global shutter storage region is formed in the second side of the silicon substrate.

17. An image sensor comprising:
a substrate with a front side and an opposing back side;
a first photodiode for a first phase detection pixel formed in the substrate;
a second photodiode for a second phase detection pixel formed in the substrate;
a first microlens on the back side of the substrate that covers the first photodiode;
a second microlens on the back side of the substrate that covers the second photodiode;
back side trench isolation formed in the substrate that extends from the back side of the substrate towards the front side of the substrate, wherein the back side trench isolation overlaps the first and second photodiodes; and
a storage region formed in the substrate, wherein the back side trench isolation shields the storage region from incident light.

18. The image sensor defined in claim 17, wherein the back side trench isolation overlaps approximately half of the first photodiode and approximately half of the second photodiode.

19. The image sensor defined in claim 18, wherein the back side trench isolation comprises tungsten and an anti-reflective coating.

20. The image sensor defined in claim 19, wherein the first and second phase detection pixels are configured to operate in a global shutter mode, and wherein the storage region is a global shutter storage region.
